(19) United States
(12) Patent Application Publication
(10) Pub. No.: US 2025/0294824 A1
(43) Pub. Date: Sep. 18, 2025

(54) TRANSISTOR AND METHOD FOR MANUFACTURING SAME

(71) Applicant: Microchip Technology Incorporated, Chandler, AZ (US)

(72) Inventors: Joseph Terence Smith, Tempe, AZ (US); Duance Edward Levine, Bend, OR (US); Robert Gilsdorf, Colorado Springs, CO (US); Nicholas Kipplan Cramer, Colorado Springs, CO (US); Shesh Mani Pandey, Gilbert, AZ (US)

(73) Assignee: Microchip Technology Incorporated, Chandler, AZ (US)

(21) Appl. No.: 18/922,872

(22) Filed: Oct. 22, 2024

Related U.S. Application Data
(60) Provisional application No. 63/564,311, filed on Mar. 12, 2024.

(51) Int. Cl. H01L 29/06; H01L 21/225; H01L 21/265; H01L 29/66; H01L 29/78

(52) U.S. Cl. CPC H10D 62/109; H01L 21/2253; H01L 21/26513; H10D 30/0291; H10D 30/66

(57) ABSTRACT

A transistor that may include a substrate. A drift layer within the substrate. A first JFET layer within a portion of the drift layer. A body layer within a portion of the drift layer. A source layer within an upper portion of the body layer. A second JFET layer within a portion of the drift layer. An insulating layer over a portion of the source layer. A gate electrode over the insulating layer.

### CROSS-REFERENCE TO RELATED APPLICATION

The present application claims priority to U.S. Provisional Patent Application No. 63/564,311, filed on Mar. 12, 2024, the contents of which are hereby incorporated by reference in their entirety.

### TECHNICAL FIELD

The present disclosure relates to semiconductor devices, and more specifically to transistors and methods for manufacturing same to increase the performance of a transistor.

### SUMMARY

This invention is about improving high voltage DMOS-type (Double-Diffused Metal Oxide Semiconductor) Silicon and Silicon Carbide Power MOSFET (Metal Oxide Semiconductor Field Effect Transistor) device on-resistance (Rdson) without degrading breakdown voltage.

According to an aspect of one or more examples, there is provided a wafer fabrication process for fabricating a transistor that may include providing a substrate, forming a drift layer within the substrate, implanting a first JFET layer within a portion of the drift layer, implanting a body layer within a portion of the drift layer, performing a first thermal drive process after implanting the body layer, implanting a source layer within an upper portion of the body layer, performing a second thermal drive process after implanting the source layer, implanting a second JFET layer within a portion of the drift layer, performing a third thermal drive process after implanting the second JFET layer, forming an insulating layer over a portion of the source layer; and forming a gate electrode over the insulating layer. The substrate may comprise a first concentration of a first type dopant. The drift layer may comprise a second concentration of the first type dopant, the first concentration is greater than the second concentration. The first JFET layer may comprise a third concentration of the first type dopant. The body layer may comprise a fourth concentration of a second type dopant. The source layer may comprise a fifth concentration of the first type dopant. The second JFET layer may comprise a sixth concentration of the first type dopant. The insulating layer may comprise polysilicon, oxide or a mixture of polysilicon and oxide. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided a transistor that may include a substrate, a drift layer within the substrate, a first JFET layer within a portion of the drift layer, a body layer within a portion of the drift layer, a source layer within an upper portion of the body layer, a second JFET layer within a portion of the drift layer, an insulating layer over a portion of the source layer, and a gate electrode over the insulating layer. The substrate may comprise a first concentration of a first type dopant. The drift layer may comprise a second concentration of the first type dopant, the first concentration is greater than the second concentration. The first JFET layer may comprise a third concentration of the first type dopant. The body layer may comprise a fourth concentration of a second type dopant. The source layer may comprise a fifth concentration of the first type dopant. The second JFET layer may comprise a sixth concentration of the first type dopant. The insulating layer may comprise polysilicon, oxide or a mixture of polysilicon and oxide. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 is a cross sectional view of a transistor according to one or more examples; and

FIG. 2 is a process flow of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

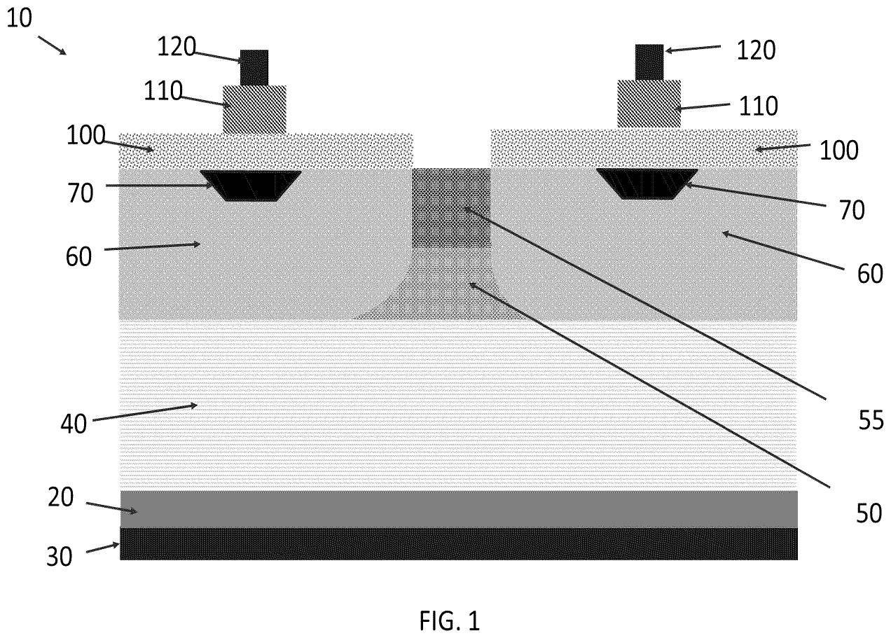

FIG. 1 is a cross sectional view of a transistor 10 according to one or more examples. As shown in FIG. 1, the transistor 10 may include a substrate 20. The substrate 20 may comprise gallium nitride, diamond, silicon carbide, sapphire, aluminum nitride or silicon. The substrate 20 may have a first concentration of a first type dopant and may be doped so as to have a resistivity of less than 25 milliohm-cm. In FIG. 1, the example transistor 10 may include a drain contact 30 that may be formed on a first side of the substrate 20. The drain contact 30 may be made from a metal, polysilicon, or other suitable material. In FIG. 1, the example transistor 10 may include a drift layer 40 that may have a second concentration of the first type dopant and may be formed on a second side of the substrate 20, the second side opposite the first side. The first concentration of first type dopant in the substrate 20 may be greater than the second concentration of first type dopant in the drift layer 40. The drift layer 40 may comprise bulk gallium nitride, diamond, silicon carbide, aluminum nitride, or silicon. In FIG. 1, the example transistor 10 may include a first JFET layer 50 that may be implanted so that the first JFET layer 50 may be deeply diffused within a portion of the drift layer 40. The first JFET layer 50 may have a third concentration of the first type dopant. In FIG. 1, the example transistor 10 may include a body layer 60 that may be implanted so that the body layer 60 may be deeply diffused into a portion of the drift layer 40. The body layer 60 may comprise a fourth concentration of a second type dopant. In FIG. 1, the example transistor 10 may include a source layer 70 that may be implanted in an upper portion of the body layer 60. The source layer 70 may comprise a fifth concentration of the first type dopant. In FIG. 1, the example transistor 10 may include a second JFET layer 55 that may be implanted within a portion of the drift layer 40 where the first JFET layer 50 was implanted. The second JFET layer 55 may have a sixth concentration of the first type dopant. The dopant concentration of the first JFET layer 50 and the second JFET layer 55 may be greater than 1e+16 atoms/cm³. The second JFET layer 55 may have a doping concentration that may be highest near the surface of the substrate 20 where the implant occurs. In contrast, the doping concentration of the first JFET layer 50 may be lowest near the lower portions of the implanted layer in order to avoid degrading the breakdown voltage of the transistor 10 of the present invention. An insulating layer 100 such as polysilicon, oxide or a mixture of polysilicon and oxide or any other insulating material may be over the source layer 70 and the body layer 60. A gate electrode 110 with a gate contact 120 may be over the insulating layer 100.

In the example transistor 10 of FIG. 1, the first type dopant may be an n-type dopant with the second type dopant being a p-type dopant. Alternatively, the first type dopant may be a p-type dopant with the second type dopant being an n-type dopant.

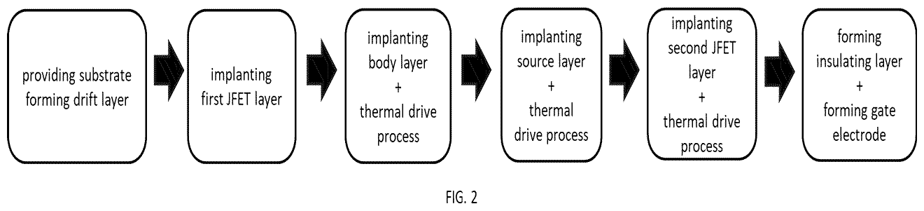

FIG. 2 shows a process flow of some of the steps in a method of manufacturing a transistor according to one or more examples. In FIG. 2, the example method may include providing a substrate. The substrate may comprise silicon, silicon carbide or GaAs. The substrate may have a first concentration of a first type dopant and may be doped so as to have a resistivity of less than 25 milliohm-cm. In FIG. 2, the example method may include forming a drift layer within the substrate. The drift layer may have a second concentration of the first type dopant. The first concentration of first type dopant in the substrate may be greater than the second concentration of first type dopant in the drift layer. The drift layer may comprise bulk gallium nitride, diamond, silicon carbide, aluminum nitride, or silicon. In FIG. 2, the example method may include implanting a first JFET layer within a portion of the drift layer so that the first JFET layer may be deeply diffused within a portion of the drift layer. The first JFET layer may have a third concentration of the first type dopant. In FIG. 2, the example method may include implanting a body layer within a portion of the drift layer so that the body layer may be deeply diffused into a portion of the drift layer. The body layer may comprise a fourth concentration of a second type dopant. Then, performing a first thermal drive process after implanting the body layer. In FIG. 2, the example method may include implanting a source layer in an upper portion of the body layer. The source layer may comprise a fifth concentration of the first type dopant. Then, performing a second thermal drive process after implanting the source layer. In FIG. 2, the example method may include implanting a second JFET layer within a portion of the drift layer that may be implanted within a portion of the drift layer where the first JFET layer was implanted. Then, performing a third thermal drive process after implanting the second JFET layer. The second JFET layer may have a sixth concentration of the first type dopant. The dopant concentration of the first JFET layer and the second JFET layer may be greater than 1e+16 atoms/cm³. The second JFET layer may have a doping concentration that may be highest near the surface of the substrate where the implant occurs. In contrast, the doping concentration of the first JFET layer may be lowest near the lower portions of the implanted layer in order to avoid degrading the breakdown voltage of the transistor of the present invention. In FIG. 2, the example method may include forming an insulating layer over a portion of the source layer. The insulating layer may comprise polysilicon, oxide or a mixture of polysilicon and oxide or any other insulating material. In FIG. 2, the example method may include forming a gate electrode over the insulating layer. The body layer and source layer may not be self-aligned to a poly gate edge. Instead, the implanting of the body layer and the source layer may rely on wafer stepper alignment tolerances.

In the example method of manufacturing a transistor of FIG. 2, the first type dopant may be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method of manufacturing a transistor, the method comprising:
providing a substrate;
forming a drift layer within the substrate;
implanting a first JFET layer within a portion of the drift layer;
implanting a body layer within a portion of the drift layer;
performing a first thermal drive process after implanting the body layer;
implanting a source layer within an upper portion of the body layer;
performing a second thermal drive process after implanting the source layer;
implanting a second JFET layer within a portion of the drift layer;
performing a third thermal drive process after implanting the second JFET layer;
forming an insulating layer over a portion of the source layer; and
forming a gate electrode over the insulating layer.

2. The method of claim 1, wherein the substrate comprises a first concentration of a first type dopant.

3. The method of claim 2, wherein the drift layer comprises a second concentration of the first type dopant, the first concentration is greater than the second concentration.

4. The method of claim 3, wherein the first JFET layer comprises a third concentration of the first type dopant.

5. The method of claim 4, wherein the body layer comprises a fourth concentration of a second type dopant.

6. The method of claim 5, wherein the source layer comprises a fifth concentration of the first type dopant.

7. The method of claim 6, wherein the second JFET layer comprises a sixth concentration of the first type dopant.

8. The method of claim 7, wherein the insulating layer comprises polysilicon, oxide or a mixture of polysilicon and oxide.

9. The method of claim 8, wherein the first type dopant comprises an n-type dopant and the second type dopant comprises a p-type dopant.

10. The method of claim 8, wherein the first type dopant comprises a p-type dopant and the second type dopant comprises an n-type dopant.

11. A transistor comprising:
a substrate;
a drift layer within the substrate;
a first JFET layer within a portion of the drift layer;
a body layer within a portion of the drift layer;
a source layer within an upper portion of the body layer;
a second JFET layer within a portion of the drift layer;
an insulating layer over a portion of the source layer; and
a gate electrode over the insulating layer.

12. The transistor of claim 11, wherein the substrate comprises a first concentration of a first type dopant.

13. The transistor of claim 12, wherein the drift layer comprises a second concentration of the first type dopant, the first concentration is greater than the second concentration.

14. The transistor of claim 13, wherein the first JFET layer comprises a third concentration of the first type dopant.

15. The transistor of claim 14, wherein the body layer comprises a fourth concentration of a second type dopant.

16. The transistor of claim 15, wherein the source layer comprises a fifth concentration of the first type dopant.

17. The transistor of claim 16, wherein the second JFET layer comprises a sixth concentration of the first type dopant.

18. The transistor of claim 17, wherein the insulating layer comprises polysilicon, oxide or a mixture of polysilicon and oxide.

19. The transistor of claim 18, wherein the first type dopant comprises an n-type dopant and the second type dopant comprises a p-type dopant.

20. The transistor of claim 18, wherein the first type dopant comprises a p-type dopant and the second type dopant comprises an n-type dopant.
